(19) United States
(12) Patent Application Publication
(10) Pub. No.: US 2025/0300035 A1
(43) Pub. Date: Sep. 25, 2025

(54) PACKAGE COMPRISING AN EMBEDDED HEAT PIPE

(71) Applicant: QUALCOMM Incorporated, San Diego, CA (US)

(72) Inventors: Aniket PATIL, San Diego, CA (US); Bohan YAN, San Diego, CA (US); Rajneesh KUMAR, San Diego, CA (US)

(21) Appl. No.: 18/609,837

(22) Filed: Mar. 19, 2024

(51) Int. Cl. H01L 23/367; H01L 23/00; H01L 23/31; H01L 25/065

(52) U.S. Cl. CPC H01L 23/3675; H01L 23/3128; H01L 24/16; H01L 25/0657; H01L 2224/16227; H01L 2225/06517; H01L 2225/06589; H01L 2924/1615; H01L 2924/181

(57) ABSTRACT

A device comprising a board; a first package coupled to the board through a plurality of solder interconnects, wherein the first package comprises: a first substrate; a first integrated device coupled to the first substrate; a heat pipe coupled to the first integrated device through a thermal interface material; a second package coupled to the first substrate through a through a plurality of inter substrate interconnects; and an encapsulation layer located between the first substrate and the second package.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages, including having improved thermal performances, while keeping the package as compact as possible.

### SUMMARY

Various features relate to packages with substrates and integrated devices.

One example provides a device comprising a board; a first package coupled to the board through a plurality of solder interconnects, wherein the first package comprises: a first substrate; a first integrated device coupled to the first substrate; a heat pipe coupled to the first integrated device through a thermal interface material; a second package coupled to the first substrate through a through a plurality of inter substrate interconnects; and an encapsulation layer located between the first substrate and the second package.

Another example provides a package comprising a first substrate; a first integrated device coupled to the first substrate; a heat pipe coupled to the first integrated device through a thermal interface material; a second substrate coupled to the first substrate through a through a plurality of inter substrate interconnects; and an encapsulation layer located between the first substrate and the second substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes an embedded heat pipe.

FIG. 2 illustrates an exemplary view of a device that includes a package with an embedded heat pipe.

FIG. 3 illustrates an exemplary view of a heat pipe.

FIG. 4 illustrates an exemplary cross sectional profile view of a package that includes an embedded heat pipe.

FIG. 5 illustrates an exemplary cross sectional profile view of a package that includes an embedded heat pipe.

FIG. 6 illustrates an exemplary cross sectional profile view of a package that includes an embedded heat pipe.

FIG. 7 illustrates an exemplary cross sectional profile view of a package that includes an embedded heat pipe.

FIG. 8 illustrates an exemplary cross sectional profile view of a package that includes an embedded heat pipe.

FIG. 9 illustrates an exemplary cross sectional profile view of a package that includes an embedded heat pipe.

FIGS. 10A-10E illustrate an exemplary sequence for fabricating a package that includes an embedded heat pipe.

FIG. 11 illustrates an exemplary flow chart of a method for fabricating a package that includes an embedded heat pipe.

FIGS. 12A-12C illustrate an exemplary sequence for fabricating a device that comprises a package with an embedded heat pipe.

FIGS. 13A-13B illustrate an exemplary sequence for fabricating a substrate.

FIG. 14 illustrates an exemplary flow chart of a method for fabricating a substrate.

FIG. 15 illustrates an exemplary cross sectional profile view of a top package that may be implemented in a package on package (POP).

FIG. 16 illustrates an exemplary cross sectional profile view of a top package that may be implemented in a package on package (PoP).

FIG. 17 illustrates an exemplary cross sectional profile view of a package that includes an embedded heat pipe.

FIG. 18 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure a device comprising a board; a first package coupled to the board through a plurality of solder interconnects, wherein the first package comprises: a first substrate; a first integrated device coupled to the first substrate; a heat pipe coupled to the first integrated device through a thermal interface material; a second package coupled to the first substrate through a through a plurality of inter substrate interconnects; and an encapsulation layer located between the first substrate and the second package. The use of the heat pipe that is embedded in a package, helps provide a package that is more efficient and effective at dissipating heat from the first integrated device, which helps improve the thermal performance of the first integrated device and/or the package.

### Exemplary Packages Comprising Embedded Heat Pipe

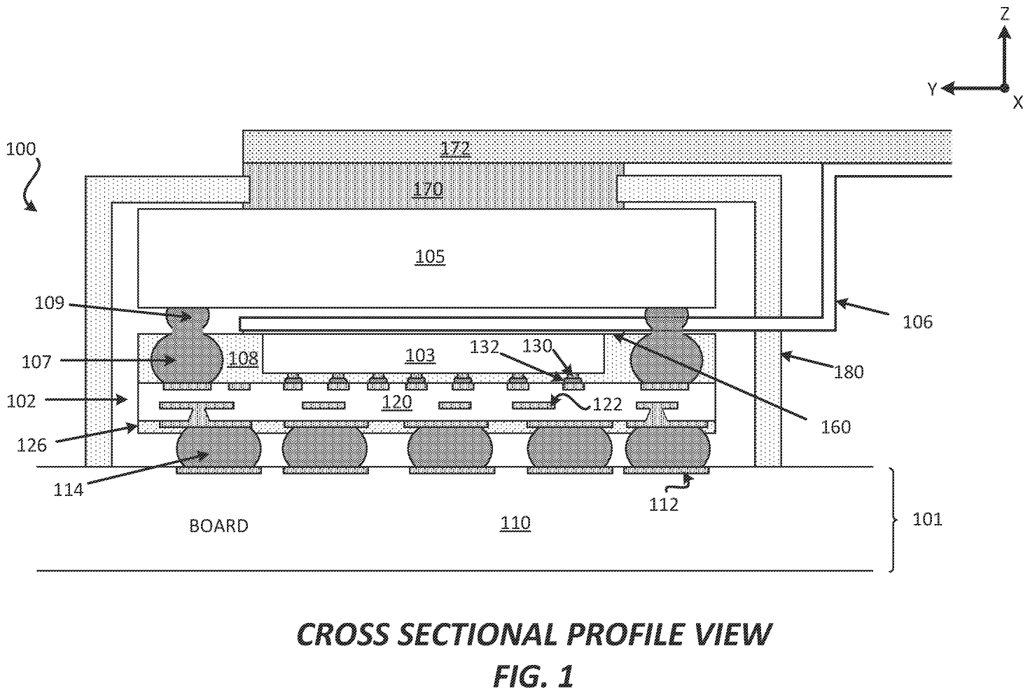

FIG. 1 illustrates a cross sectional profile view of a package 100 that includes an embedded heat pipe. The embedded heat pipe is located between two substrates. The package 100 may be implemented as part of a package on package (POP). The package 100 is coupled to a board 101 through a plurality of solder interconnects 114. The board 101 includes at least one board dielectric layer 110 and a plurality of board interconnects 112. The board 101 may include a printed circuit board (PCB).

The package 100 includes a substrate 102 (e.g., first substrate), an integrated device 103 (e.g., first integrated device), a package 105 (e.g., top package), a heat pipe 106, and an encapsulation layer 108. The substrate 102 includes a dielectric layer 120, a plurality of interconnects 122 and a solder resist layer 126. The substrate 102 is coupled to the board 101 through the plurality of solder interconnects 114. The integrated device 103 is coupled to the substrate 102 through at least a plurality of solder interconnects 132. For example, the integrated device 103 is coupled to a plurality of interconnects 122 of the substrate 102 through a plurality of pillar interconnects 130 and/or a plurality of solder interconnects 132. A plurality of solder interconnects 107 are coupled to the plurality of interconnects 122 of the substrate 102. The encapsulation layer 108 may at least partially encapsulate the integrated device 103 and the plurality of solder interconnects 107.

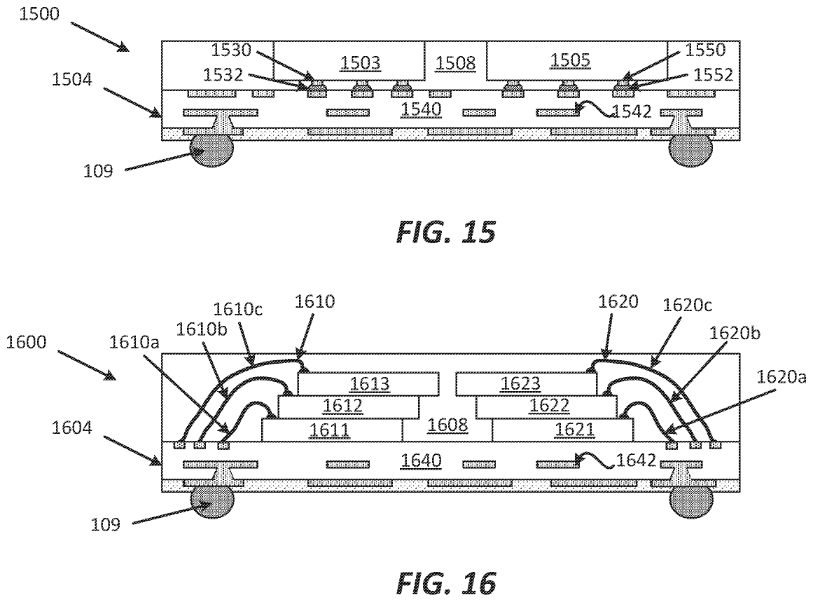

The package 105 is coupled to the substrate 102 through a plurality of solder interconnects 109 and a plurality of solder interconnects 107. The plurality of solder interconnects 109 may be coupled to the plurality of solder interconnects 107. In some implementations, the plurality of solder interconnects 109 and the plurality of solder interconnects 107 may be considered part of the same plurality of solder interconnects. The plurality of solder interconnects 109 and the plurality of solder interconnects 107 may be considered examples of inter substrate interconnects. The integrated device 103, the encapsulation layer 108, the plurality of solder interconnects 107 and the plurality of solder interconnects 109 are located between the substrate 102 and the package 105. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process. In some implementations, the package 105 may include at least one integrated device and at least one substrate (e.g., interposer). In some implementations, the package 105 may include at least one integrated device and a metallization portion comprising a plurality of metallization interconnects (e.g., redistribution interconnects). The plurality of solder interconnects 109 may be considered part of the package 105. Different implementations may use different configurations of the package 105. More detailed examples of the package 105 are illustrated and described below in at least FIGS. 15 and 16. As will be described below, the package 105 may include a plurality of wire bonds, a plurality of solder interconnects and/or an encapsulation layer.

FIG. 1 illustrates the heat pipe 106 embedded in the package 100. The heat pipe 106 is coupled to the integrated device 103 through a thermal interface material 160. For example, the heat pipe 106 is coupled to a back side of the integrated device 103 through the thermal interface material 160. The thermal interface material 160 may touch the back side of the integrated device 103 and the encapsulation layer 108. The back side of the integrated device 103 may be a side of the integrated device 103 that includes a die substrate (e.g., silicon substrate). The heat pipe 106 may be located between the substrate 102 and the package 105. The heat pipe 106 may be located between the package 105 and the encapsulation layer 108. A part of the heat pipe 106 is located in the package 100 and another part of the heat pipe 106 may be located outside of the package 100. For example, a part of the heat pipe 106 may be located between the substrate 102 and the package 105, and another part of the heat pipe 106 may not be located between the substrate 102 and the package 105. The heat pipe 106 is configured to dissipate heat away from the integrated device 103. At least some heat from the integrated device 103 may dissipate through the back side of the integrated device 103, the thermal interface material 160 and the heat pipe 106. Placing the heat pipe 106 as close as possible to the integrated device 103 helps provide with an efficient and effective way of dissipating heat from the integrated device 103, which helps improve the thermal performance of the integrated device 103 and/or the package 100.

A thermal interface material 170 is coupled to the back side of the package 105. A heat sink 172 is coupled to the thermal interface material 170. The heat sink 172 may be coupled to the back side of the package 105 through the thermal interface material 170. The back side of the package 105 may be a side of the package 105 that includes an encapsulation layer. Different implementations may use different configurations of a heat sink. In some implementations, the heat sink 172 may include a metal component. In some implementations, the heat sink 172 may include a heat pipe. In some implementations, the heat sink 172 may include a vapor chamber. The heat sink 172 is coupled to and touching the heat pipe 106. In some implementations, the heat pipe 106 may be coupled to the heat sink 172 through a thermal interface material (not shown). The heat sink 172 may considered part of the package 100.

A frame 180 is coupled to the board 101. The frame 180 may be bonded to the board 101. The frame 180 may at least partially surround the package 100. The frame 180 may at least partially laterally surround the package 100. The frame 180 may include a top portion that is located above the package 100. The package 100 may be located between the top portion of the frame 180 and the board 101. The frame 180 may be configured as a casing. The frame 180 may be configured as an electromagnetic interference (EMI) shield casing. The frame 180 may include a metal. The shape of the frame 180 may be formed through a stamping process. The frame 180 may include several openings. The heat pipe 106 may extend through the frame 180 through an opening in the frame 180. There may be an opening in the frame 180, above the package 105. The thermal interface material 170 may be located at least partially in the opening of the frame 180. The heat sink 172 may be located above the frame 180.

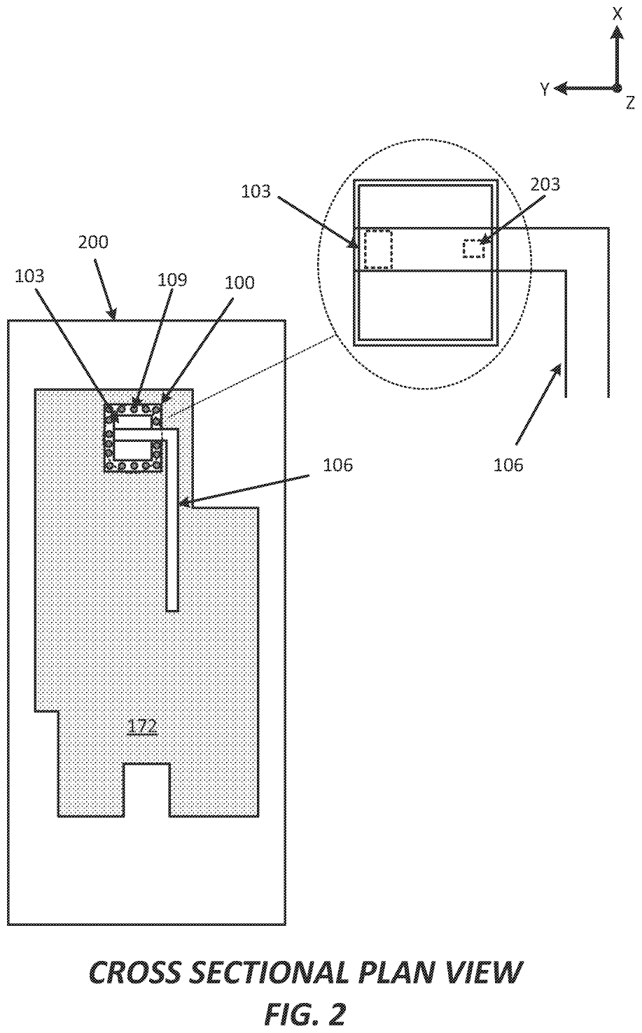

FIG. 2 illustrates a device 200 that includes the package 100. The device 200 may be a mobile device, such as a mobile phone. However, the device 200 may be any kind of electronic device. The device 200 includes the integrated device 103, the plurality of solder interconnects 109 and the heat pipe 106. The integrated device 103 includes a plurality of cores 203. The heat pipe 106 is located in the device 200, such that the heat pipe 106 vertically overlaps with at least part of the integrated device 103. For example, the heat pipe 106 may vertically overlap with the plurality of cores 203 of the integrated device 103. This may be done, since the plurality of cores 203 may generate a lot of heat when the integrated device 103 operates, and placing the heat pipe 106 as close to the plurality of cores 203 helps ensure the maximum amount of heat transfer possible.

FIG. 2 illustrates that the heat pipe 106 may be located laterally between two solder interconnects from the plurality of solder interconnects 109. As mentioned above, the plurality of solder interconnects 109 may be examples of inter substrate interconnects. As such, the heat pipe 106 may be located laterally between two inter substrate interconnects from the plurality of inter substrate interconnects. As shown in FIG. 2, the heat pipe 106 may extend in the horizontal direction. For example, the heat pipe 106 may extend in the Y direction (e.g., first horizontal direction) and extend in the X direction (e.g., second horizontal direction). As shown in FIG. 2, the heat pipe 106 may also extend in the Z direction (e.g., vertical direction). The heat pipe 106 is coupled to the heat sink 172. The heat pipe 106 may be coupled to the heat sink 172 through a thermal interface material. It is noted that different implementations may have a heat pipe 106 with different configurations, materials, shapes, sizes, widths and/or lengths. Similarly, different implementations, may have a heat sink 172 with different configurations, materials, shapes, sizes, widths and/or lengths. The device 200 may include any of the packages described in the disclosure. The device 200 may include the board 101 and the frame 180.

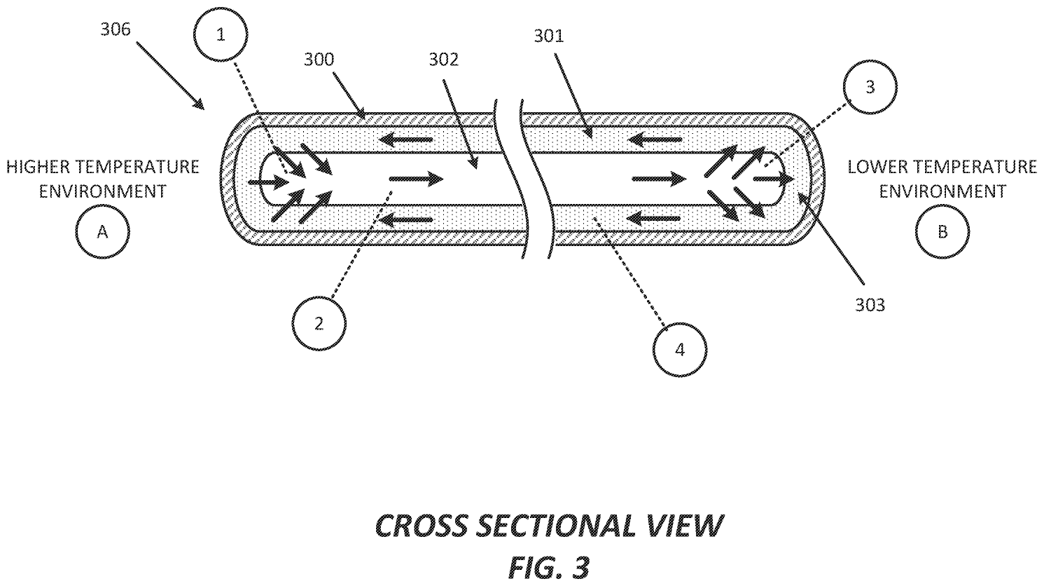

FIG. 3 illustrates an example of how a heat pipe 306 may function to provide heat dissipation. The heat pipe 306 may be a representation of the heat pipe 106. The heat pipe 306 may be a two phase heat dissipation device. The heat pipe 306 has a straight shape. However, the heat pipe 306 may include other shapes that includes curves, turns and/or bends. The heat pipe 306 includes a casing 300, a wick 301, a cavity 302 and a fluid 303. The wick 301 is located along the casing 300. The cavity 302 may be defined by the wick 301. The fluid 303 is located in the heat pipe 306. The fluid 303 may have different phases depending on the temperatures in the heat pipe 306. Different implementations may use different fluids for the fluid 303.

A part of the heat pipe 306 may be located in/near a higher temperature environment A. In one example, the higher temperature environment A may be near an integrated device. Another part of the heat pipe 306 may be located in/near a lower temperature environment B. In one example, the lower temperature environment B may be a heat sink. At stage 1 of FIG. 3, the liquid of the fluid 303 in the wick 301 evaporates into vapor, which absorbs the thermal energy of the higher temperature environment B. At stage 2 of FIG. 3, the vapor of the fluid 303 then migrates along the cavity 302 towards the lower temperature environment B. At stage 3 of FIG. 3, the vapor of the fluid 303 condenses back to a liquid and is absorbed by the wick 301, releasing the thermal energy in the lower temperature environment B. The liquid of the fluid 303 flows through the wick 301 towards the higher temperature environment A. It is noted that fluid 303 may have different phases while inside the heat pipe 306. Thus, in some implementations, some of the fluid 303 may be an liquid state and some of the fluid 303 may be in a vapor state.

Table 1 below illustrates how a heat pipe that is embedded in a package may help improve the thermal performance of the an integrated device and/or a package.

TABLE 1
Thermal properties

| | Device without Embedded | Device with Embedded |
|---|---|---|
| | Heat Pipe in Package | Heat Pipe in Package |
| Tj(C) | 188.1 | 162.4 |
| Rja (C/W) | 15.5 (ref) | 13.1 (−15.5%) |
| JTPE (W) | 5.2 (ref) | 6.1 (+17.3%) |

Table 1 illustrates an example of how an embedded heat pipe in package that can improve the thermal performance of an integrated device and/or a package. For example, the junction temperature of an integrated device in a package without an embedded heat pipe may reach 188.1° C., while the junction temperature of an integrated device in a package with an embedded heat pipe may reach 162.4° C. Moreover, the use of the embedded heat pipe shows a 15.5% reduction in junction-to-ambient resistance (Rja) and a 17.3% increase in package junction thermal power envelop (JTPE). Typically, the lower the in junction-to-ambient resistance the better. While the higher the package junction thermal power envelop, the better. It is noted that the values of Table 1 is merely exemplary. Different implementations may have different thermal performances.

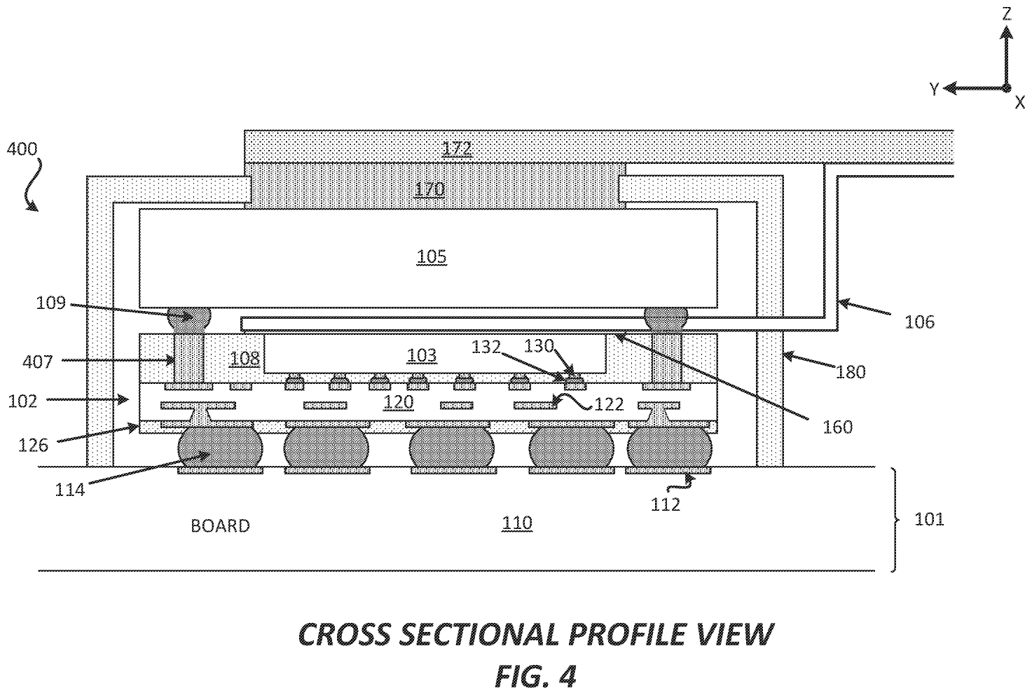

FIG. 4 illustrates a package 400 that includes an embedded heat pipe. The package 400 is similar to the package 100 of FIG. 1, and may include similar components that are arranged in a similar manner, as described for the package 100. The package 400 may include a different configuration of inter substrate interconnects from the package 100. The package 400 includes a substrate 102 (e.g., first substrate), an integrated device 103 (e.g., first integrated device), a package 105 (e.g., top package), a heat pipe 106, an encapsulation layer 108, a plurality of solder interconnects 109 and a plurality of through encapsulation layer interconnects 407. The plurality of solder interconnects 109 and/or a plurality of through encapsulation layer interconnects 407 may be examples of a plurality of inter substrate interconnects. The plurality of through encapsulation layer interconnects 407 may be located in the encapsulation layer 108. The plurality of through encapsulation layer interconnects 407 may be coupled to the plurality of interconnects 122 of the substrate 102. The plurality of solder interconnects 109 may be coupled to the plurality of through encapsulation layer interconnects 407. The plurality of solder interconnects 109 may be coupled to the package 105. The package 105 is coupled to the substrate 102 through the plurality of solder interconnects 109 and the plurality of through encapsulation layer interconnects 407. The plurality of solder interconnects 109 and the plurality of through encapsulation layer interconnects 407 are located between the substrate 102 and the package 105. The plurality of solder interconnects 109 may be considered part of the package 105.

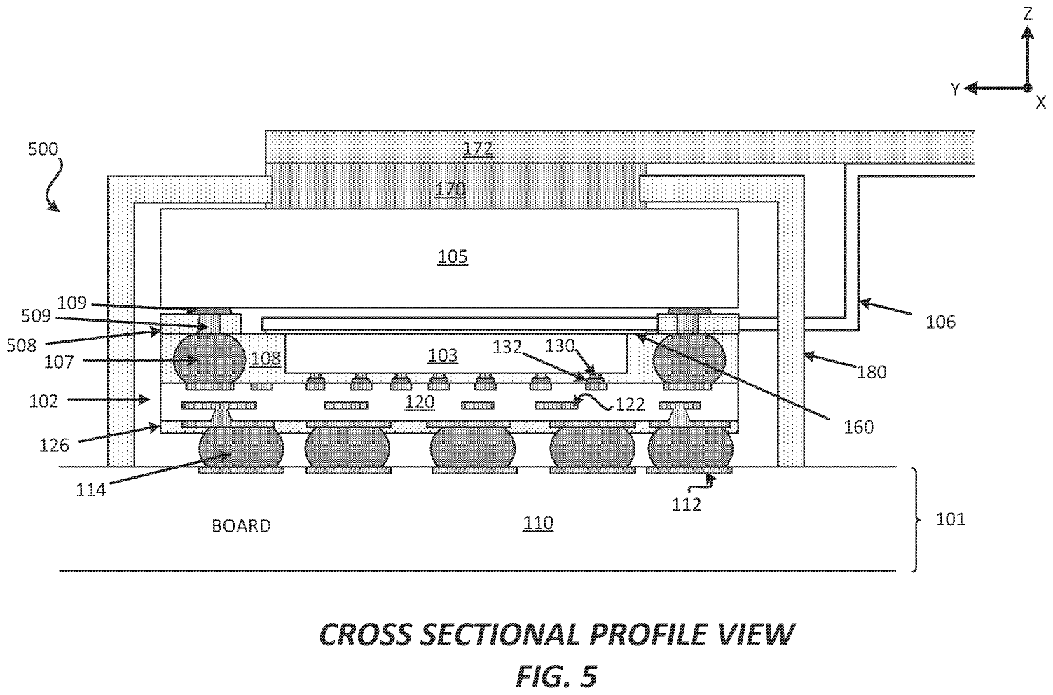

FIG. 5 illustrates a package 500 that includes an embedded heat pipe. The package 500 is similar to the package 100 of FIG. 1, and may include similar components that are arranged in a similar manner, as described for the package 500. The package 500 may include a different configuration of inter substrate interconnects from the package 100. The package 500 includes a substrate 102 (e.g., first substrate), an integrated device 103 (e.g., first integrated device), a package 105 (e.g., top package), a heat pipe 106, an encapsulation layer 108, an encapsulation layer 508, a plurality of solder interconnects 107, a plurality of solder interconnects 109 and a plurality of through encapsulation layer interconnects 509.

The plurality of solder interconnects 107, the plurality of solder interconnects 109 and/or a plurality of through encapsulation layer interconnects 509 may be examples of a plurality of inter substrate interconnects. The plurality of through encapsulation layer interconnects 209 may be located in the encapsulation layer 508. The encapsulation layer 608 may include a mold, a resin and/or an epoxy. The encapsulation layer 508 may be a means for encapsulation. The encapsulation layer 508 may be provided by using a compression and transfer molding process, a sheet molding process, or a liquid molding process. The plurality of through encapsulation layer interconnects 209 may be coupled to the plurality of solder interconnects 107 and the plurality of solder interconnects 109. The plurality of solder interconnects 107 are coupled to the plurality of interconnects 122 of the substrate 102. The plurality of solder interconnects 109 are coupled to the package 105. The package 105 is coupled to the substrate 102 through the plurality of solder interconnects 109, the plurality of through encapsulation layer interconnects 509 and/or the plurality of solder interconnects 107. The plurality of solder interconnects 109 may be considered part of the package 105.

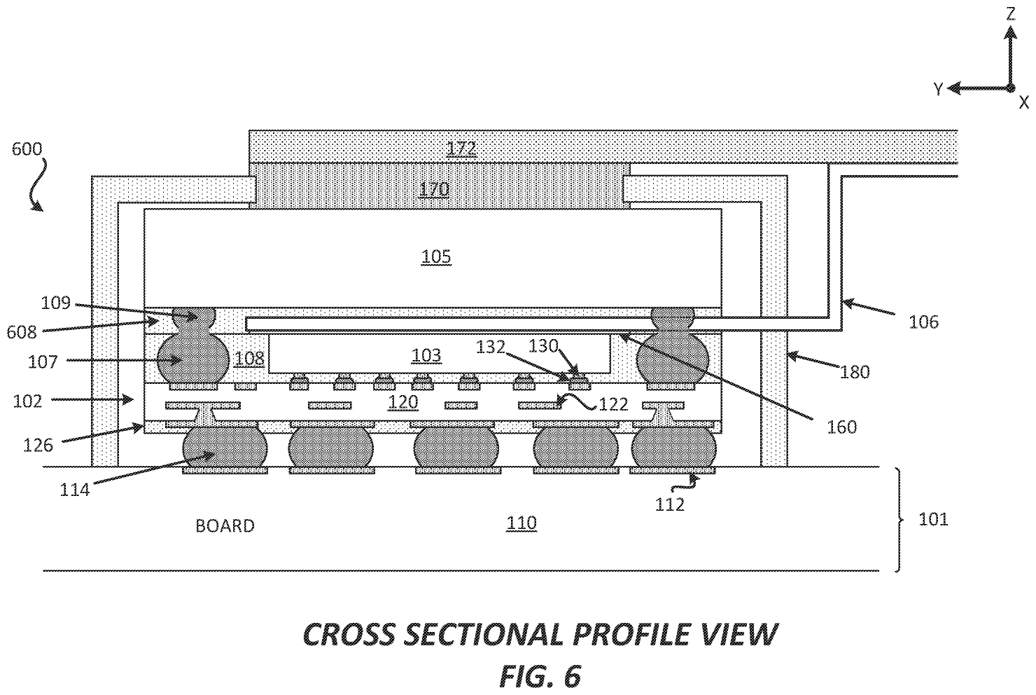

FIG. 6 illustrates a package 600 that includes an embedded heat pipe. The package 600 is similar to the package 100 of FIG. 1, and may include similar components that are arranged in a similar manner, as described for the package 600. The package 600 may include a different configuration of inter substrate interconnects from the package 100. The package 600 includes a substrate 102 (e.g., first substrate), an integrated device 103 (e.g., first integrated device), a package 105 (e.g., top package), a heat pipe 106, an encapsulation layer 108, an encapsulation layer 608, a plurality of solder interconnects 107 and a plurality of solder interconnects 109.

As shown in FIG. 6, the encapsulation layer 608 at least partially encapsulates the plurality of solder interconnects 109 and the heat pipe 106. FIG. 6 illustrates that the heat pipe 106 is located and/or embedded in an encapsulation layer. The encapsulation layer 608 is located between the package 105 and the substrate 102. The encapsulation layer 608 may include a mold, a resin and/or an epoxy. The encapsulation layer 608 may be a means for encapsulation. The encapsulation layer 608 may be provided by using a compression and transfer molding process, a sheet molding process, or a liquid molding process. The encapsulation layer 608 may be considered part of the encapsulation layer 108, and vice versa.

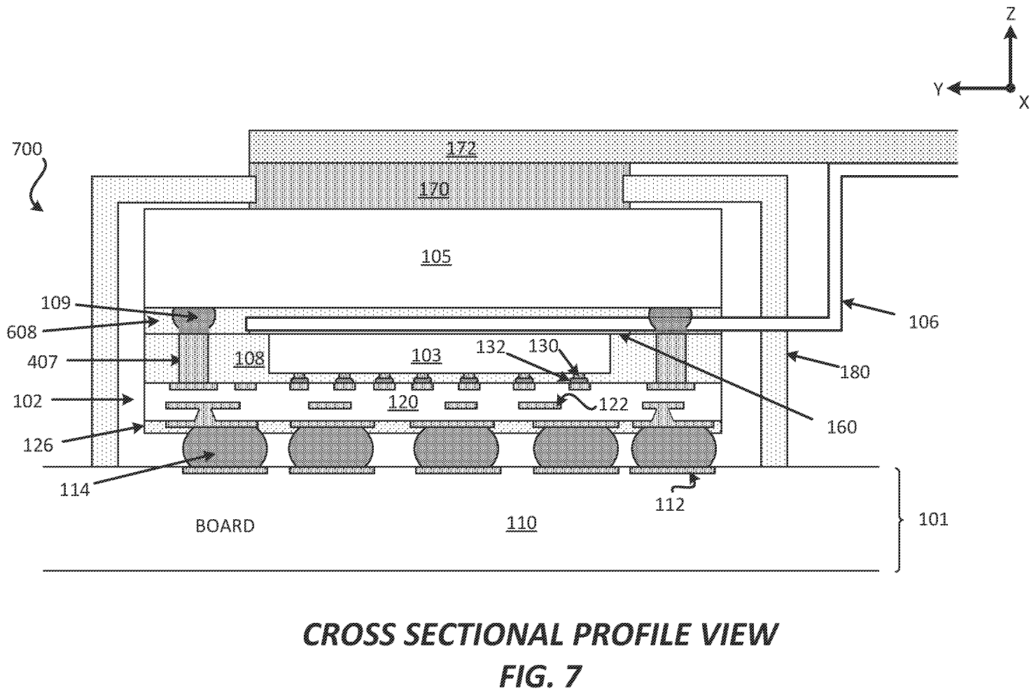

FIG. 7 illustrates a package 700 that includes an embedded heat pipe. The package 700 is similar to the package 100 of FIG. 1 and/or the package 400 of FIG. 4, and may include similar components that are arranged in a similar manner, as described for the package 100 and/or the package 400. The package 700 may include a different configuration of inter substrate interconnects from the package 100. The package 700 includes a substrate 102 (e.g., first substrate), an integrated device 103 (e.g., first integrated device), a package 105 (e.g., top package), a heat pipe 106, an encapsulation layer 108, an encapsulation layer 608, a plurality of through encapsulation layer interconnects 407 and a plurality of solder interconnects 109.

As shown in FIG. 7, the encapsulation layer 608 at least partially encapsulates the plurality of solder interconnects 109 and the heat pipe 106. FIG. 7 illustrates that the heat pipe 106 is located and/or embedded in an encapsulation layer. The encapsulation layer 608 is located between the package 105 and the substrate 102. The encapsulation layer 608 may include a mold, a resin and/or an epoxy. The encapsulation layer 608 may be a means for encapsulation. The encapsulation layer 608 may be provided by using a compression and transfer molding process, a sheet molding process, or a liquid molding process. The encapsulation layer 608 may be considered part of the encapsulation layer 108, and vice versa.

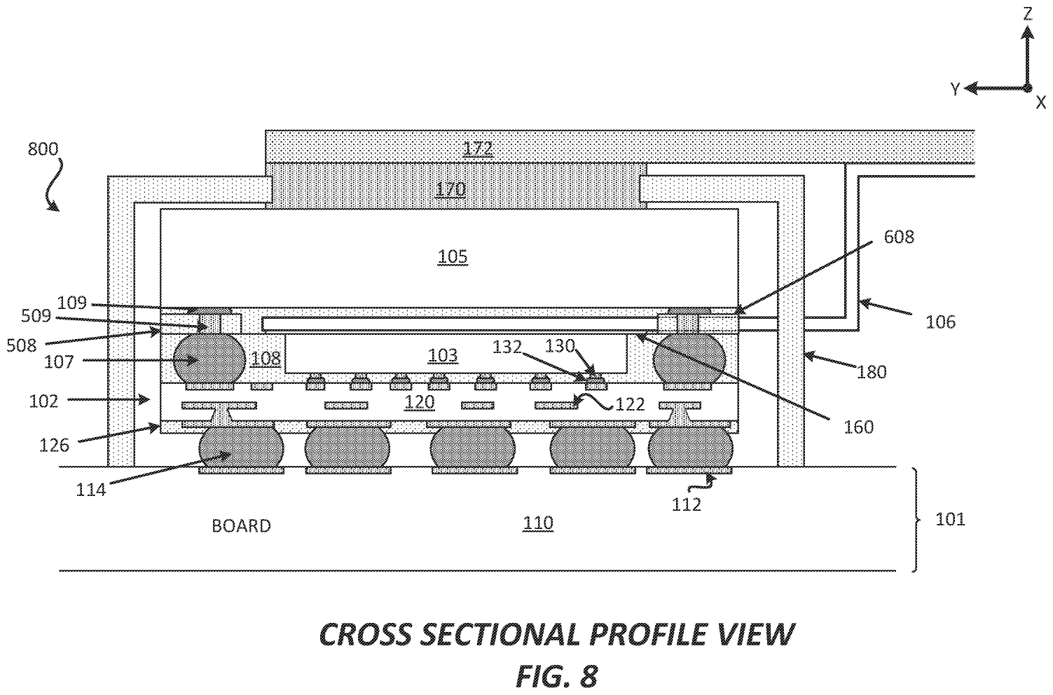

FIG. 8 illustrates a package 800 that includes an embedded heat pipe. The package 800 is similar to the package 100 of FIG. 1 and/or the package 500 of FIG. 5, and may include similar components that are arranged in a similar manner, as described for the package 100 and/or the package 500. The package 800 may include a different configuration of inter substrate interconnects from the package 100. The package 800 includes a substrate 102 (e.g., first substrate), an integrated device 103 (e.g., first integrated device), a package 105 (e.g., top package), a heat pipe 106, an encapsulation layer 108, an encapsulation layer 508, an encapsulation layer 608, a plurality of through encapsulation layer interconnects 509, a plurality of solder interconnects 107 and a plurality of solder interconnects 109.

As shown in FIG. 8, the encapsulation layer 608 at least partially encapsulates the plurality of solder interconnects 109 and the heat pipe 106. FIG. 8 illustrates that the heat pipe 106 is located and/or embedded in an encapsulation layer. The encapsulation layer 608 is located between the package 105 and the substrate 102. The encapsulation layer 608 may include a mold, a resin and/or an epoxy. The encapsulation layer 608 may be a means for encapsulation. The encapsulation layer 608 may be provided by using a compression and transfer molding process, a sheet molding process, or a liquid molding process. The encapsulation layer 608 may be considered part of the encapsulation layer 508, and vice versa. The encapsulation layer 608 may be considered part of the encapsulation layer 108, and vice versa.

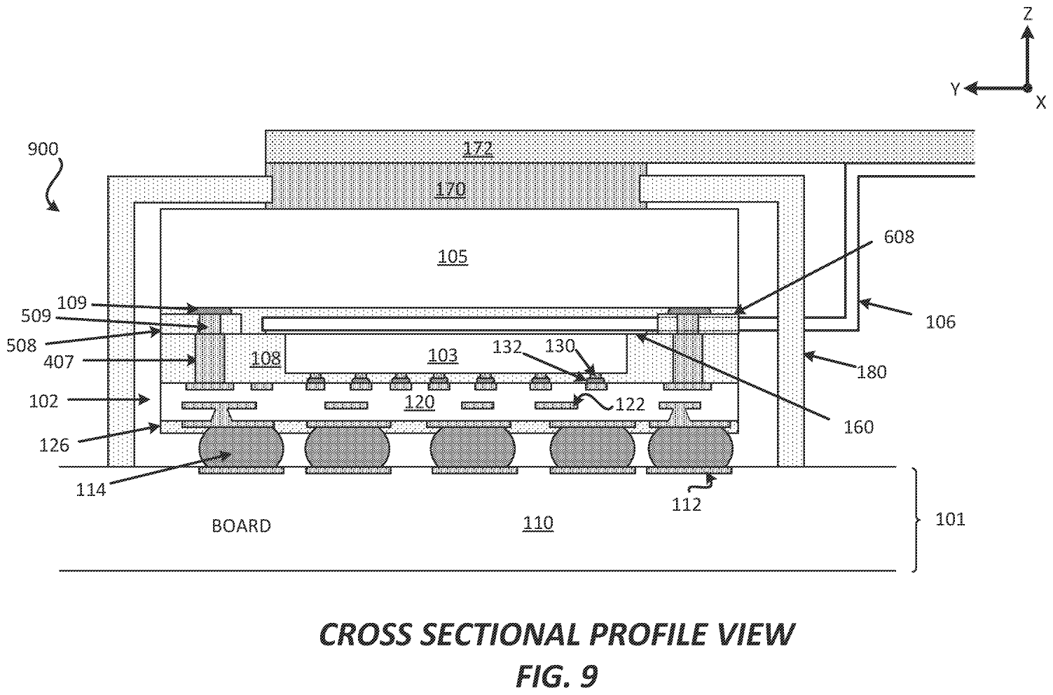

FIG. 9 illustrates a package 900 that includes an embedded heat pipe. The package 900 is similar to the package 100 of FIG. 1, the package 500 of FIG. 5 and/or the package 800, and may include similar components that are arranged in a similar manner, as described for the package 100, the package 500 and/or the package 800. The package 900 may include a different configuration of inter substrate interconnects from the package 100. The package 800 includes a substrate 102 (e.g., first substrate), an integrated device 103 (e.g., first integrated device), a package 105 (e.g., top package), a heat pipe 106, an encapsulation layer 108, an encapsulation layer 508, an encapsulation layer 608, a plurality of through encapsulation layer interconnects 509, a plurality of through encapsulation layer interconnects 407 and a plurality of solder interconnects 109.

The plurality of through encapsulation layer interconnects 407 are coupled to the plurality of interconnects 122 of the substrate 102. The plurality of through encapsulation layer interconnects 407 are coupled to the plurality of through encapsulation layer interconnects 509. The plurality of solder interconnects 109 are coupled to the plurality of through encapsulation layer interconnects 509. The package 105 is coupled to the substrate 102 through the plurality of solder interconnects 109, the plurality of through encapsulation layer interconnects 509 and/or the plurality of through encapsulation layer interconnects 407.

As shown in FIG. 9, the encapsulation layer 608 at least partially encapsulates the plurality of solder interconnects 109 and the heat pipe 106. FIG. 9 illustrates that the heat pipe 106 is located and/or embedded in an encapsulation layer. The encapsulation layer 608 is located between the package 105 and the substrate 102. The encapsulation layer 608 may include a mold, a resin and/or an epoxy. The encapsulation layer 608 may be a means for encapsulation. The encapsulation layer 608 may be provided by using a compression and transfer molding process, a sheet molding process, or a liquid molding process. The encapsulation layer 608 may be considered part of the encapsulation layer 508, and vice versa. The encapsulation layer 608 may be considered part of the encapsulation layer 108, and vice versa.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 400) may be implemented in a radio frequency (RF) package. The RF package may be a radio frequency front end (RFFE) package. A package (e.g., 100, 400) may be configured to provide Wireless Fidelity (WiFi) communication and/or cellular communication (e.g., 2G, 3G, 4G, 5G). The packages (e.g., 100, 600) may be configured to support Global System for Mobile (GSM) Communications, Universal Mobile Telecommunications System (UMTS), and/or Long-Term Evolution (LTE). The packages (e.g., 100, 400) may be configured to transmit and receive signals having different frequencies and/or communication protocols.

### Exemplary Sequence for Fabricating a Package Comprising an Embedded Heat Pipe

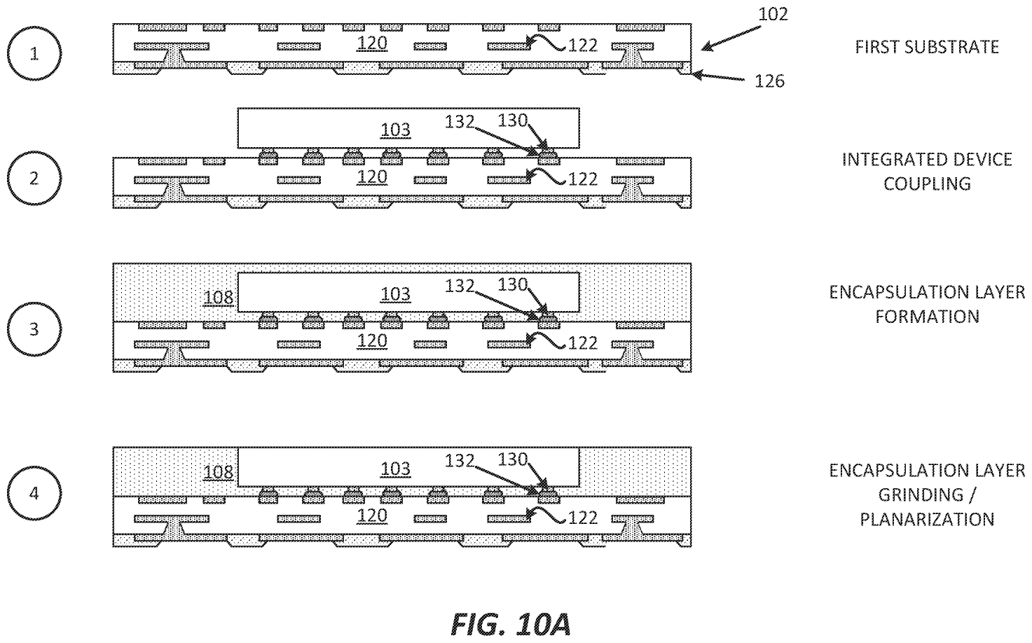

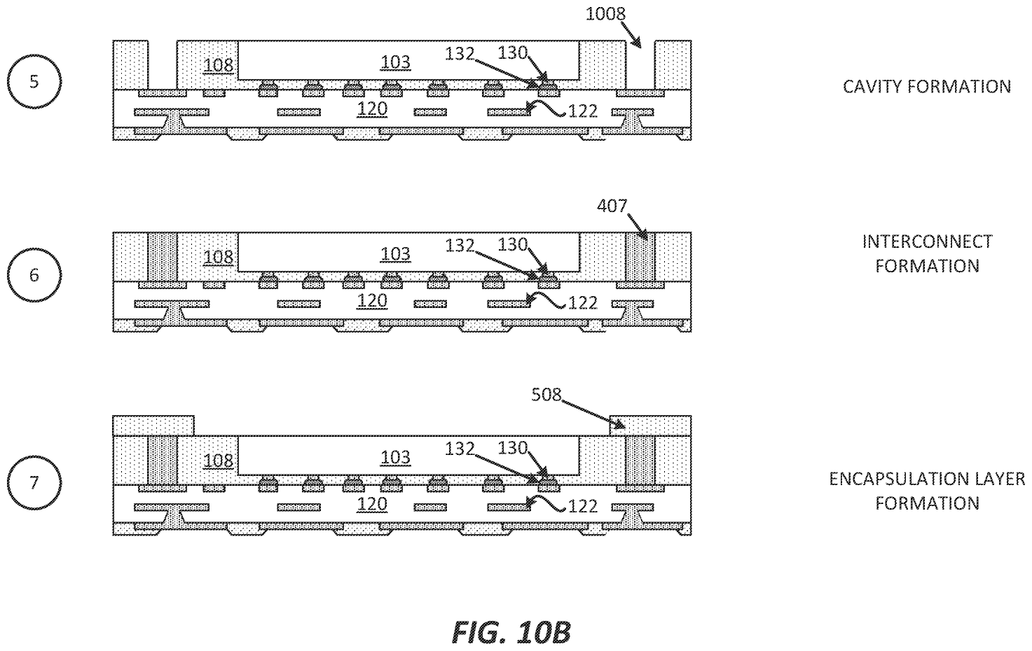

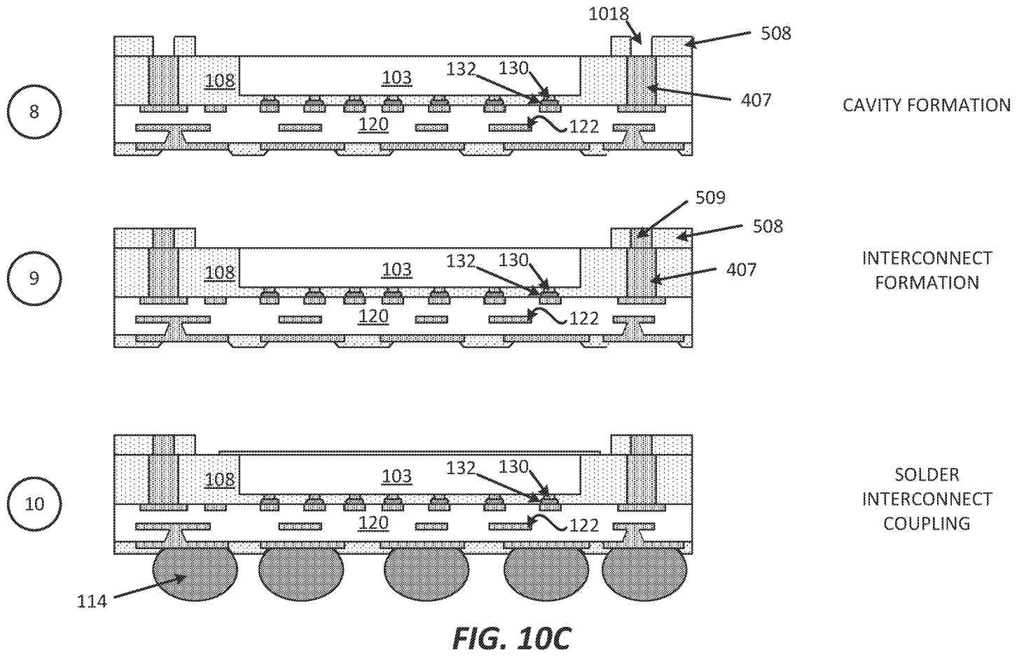

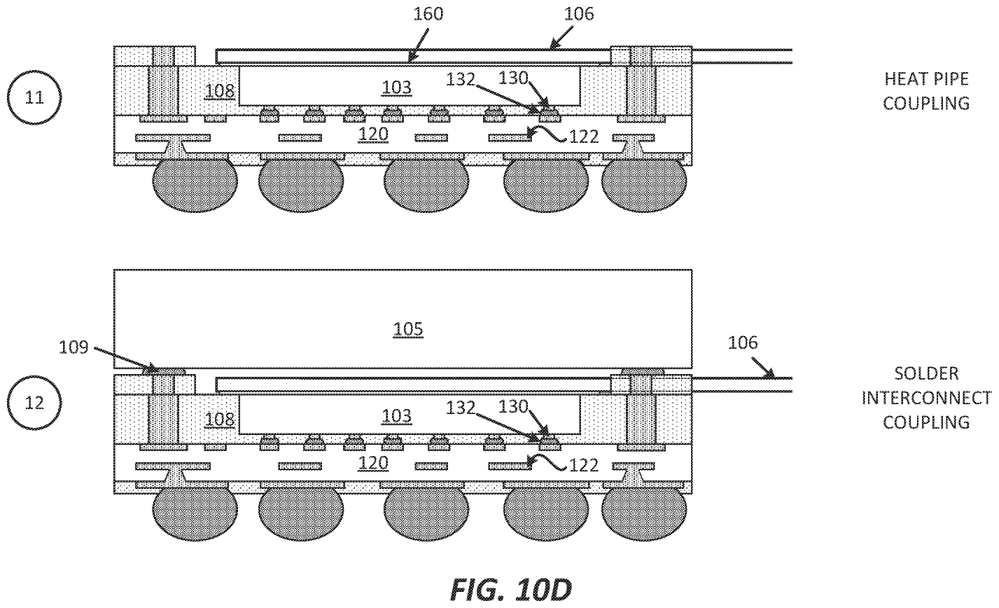

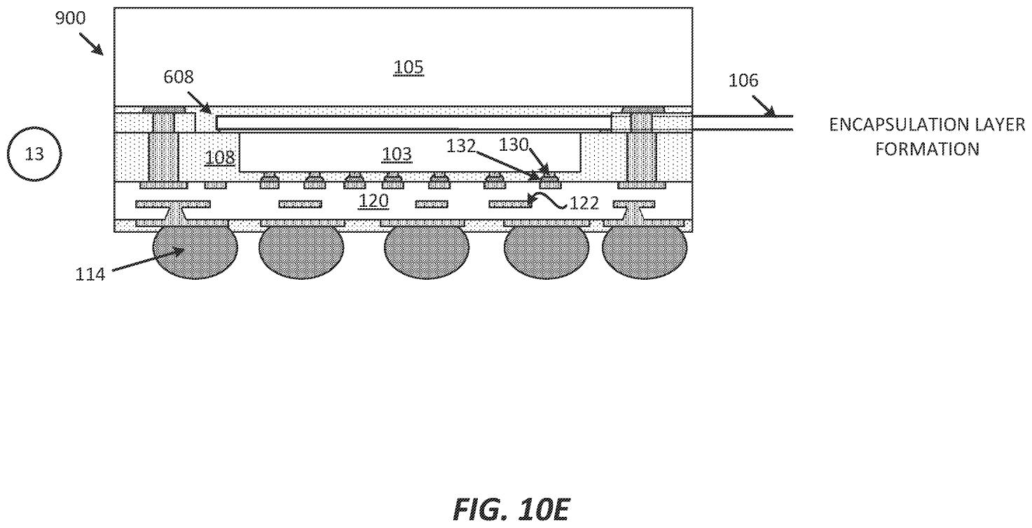

In some implementations, fabricating a package includes several processes. FIGS. 10A-10E illustrate an exemplary sequence for providing or fabricating a package. In some implementations, the sequence of FIGS. 10A-10E may be used to provide or fabricate the package 1000. However, the process of FIGS. 10A-10E may be used to fabricate any of the packages (e.g., 100) described in the disclosure.

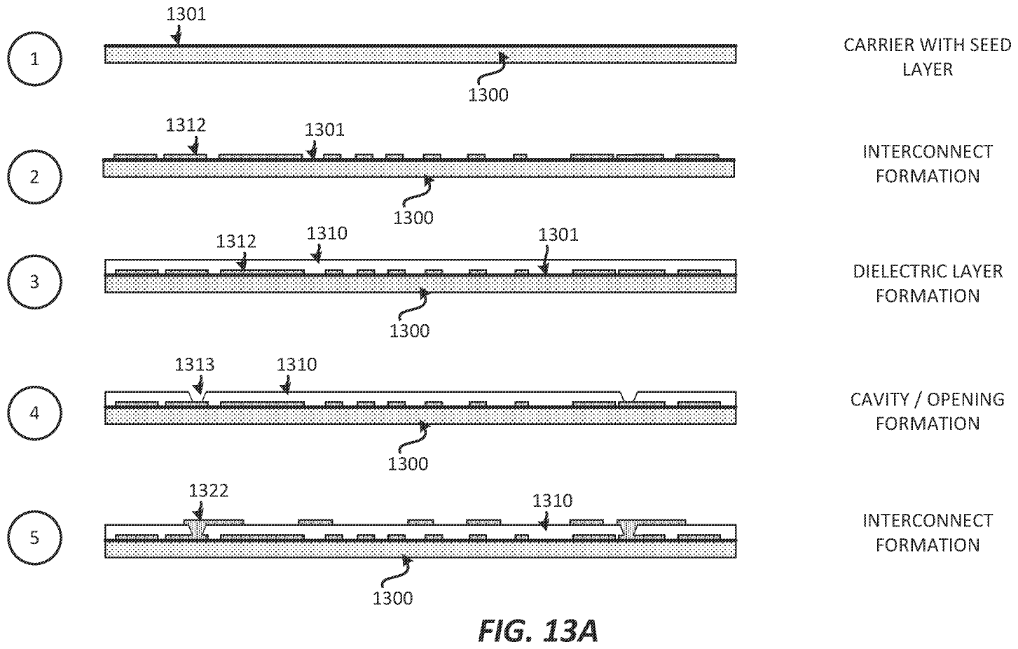

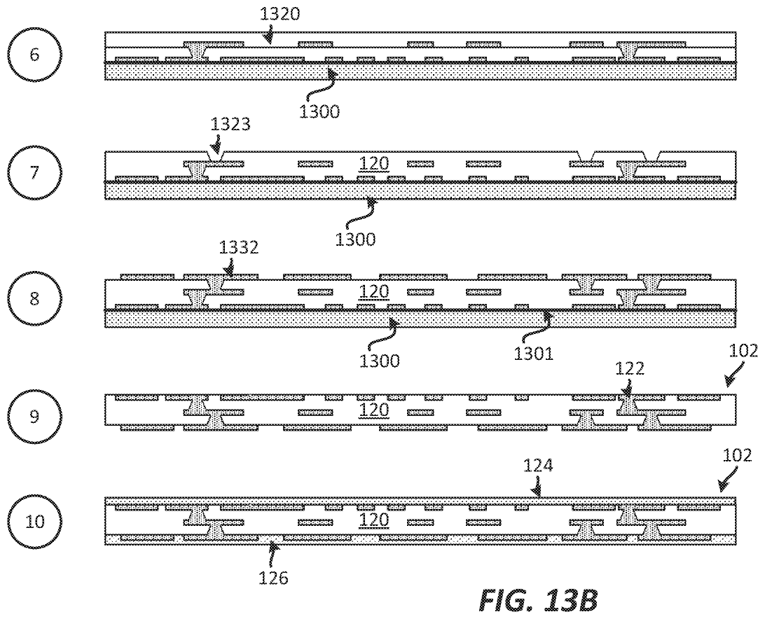

It should be noted that the sequence of FIGS. 10A-10E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.
Stage 1, as shown in FIG. 10A, illustrates a state after a substrate 102 is provided. The substrate 102 may be a first substrate. The substrate 102 includes at least one dielectric layer 120, a plurality of interconnects 122. The substrate 102 may include a first surface (e.g., top surface) and a second surface (e.g., bottom surface). The substrate 102 may include solder resist layers. The substrate 102 may be fabricated using the method as described in FIGS. 13A-13B.
Stage 2 illustrates a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102. A front side of the integrated device 103 may be coupled to the substrate 102 through the plurality of pillar interconnects 130 and the plurality of solder interconnects 132.
Stage 3 illustrate a state after an encapsulation layer 108 is formed and coupled to the substrate 102. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process. The encapsulation layer 108 may at least partially encapsulate the integrated device 103.
Stage 4 illustrates a state after planarization of the encapsulation layer 108. A portion of the encapsulation layer 108 may be removed through a grinding process and/or a polishing process. In some implementations, part of the integrated device 103 may also be removed. For example, part of the back side of the integrated device 103 may be removed so that the surface of the back side of the integrated device 103 is planar with the surface of the encapsulation layer 108.
Stage 5, as shown in FIG. 10B, illustrates a state after a plurality of cavities 1008 are formed in the encapsulation layer 108. The plurality of cavities 1008 may expose portions of the plurality of interconnects 122. A laser ablation process may be used to form the plurality of cavities 1008. However, different implementations may use different processes to form the plurality of cavities 1008.
Stage 6 illustrates a state after a plurality of through encapsulation layer interconnects 407 are formed in the plurality of cavities 1008 of the encapsulation layer 108. A plating process may be used to form the plurality of through encapsulation layer interconnects 407. However, different implementations may use different processes to form the plurality of through encapsulation layer interconnects 407. The plurality of through encapsulation layer interconnects 407 may be an example of a plurality of inter substrate interconnects. In some implementations, the plurality of through encapsulation layer interconnects 407 is formed and then the encapsulation layer 108 is formed that at least partially encapsulates the plurality of through encapsulation layer interconnects 407.

In some implementations, a plurality of solder interconnects (e.g., 107) may be used instead of the plurality of through encapsulation layer interconnects 407. In such instances, the plurality of solder interconnects (e.g., 107) may be coupled to the plurality of interconnects 122 through a solder reflow process, and then the encapsulation layer 108 is formed that at least partially encapsulates the plurality of solder interconnects 107.
Stage 7 illustrates a state after the encapsulation layer 508 is formed. The encapsulation layer 508 may be formed and coupled to the encapsulation layer 108. The encapsulation layer 508 may include a mold, a resin and/or an epoxy. The encapsulation layer 508 may be a means for encapsulation. The encapsulation layer 508 may be provided by using a compression and transfer molding process, a sheet molding process, or a liquid molding process.
Stage 8, as shown in FIG. 10C, illustrates a state after a plurality of cavities 1018 are formed in the encapsulation layer 508. The plurality of cavities 1018 may expose portions of the plurality of through encapsulation layer interconnects 407. A laser ablation process may be used to form the plurality of cavities 1018. However, different implementations may use different processes to form the plurality of cavities 1018.
Stage 9 illustrates a state after a plurality of through encapsulation layer interconnects 509 are formed in the plurality of cavities 1018 of the encapsulation layer 508. A plating process may be used to form the plurality of through encapsulation layer interconnects 509. However, different implementations may use different processes to form the plurality of through encapsulation layer interconnects 509. The plurality of through encapsulation layer interconnects 509 may be an example of a plurality of inter substrate interconnects. In some implementations, the plurality of through encapsulation layer interconnects 509 is formed and then the encapsulation layer 508 is formed that at least partially encapsulates the plurality of through encapsulation layer interconnects 509.
Stage 10 illustrates a state after a plurality of solder interconnects 114 are coupled to the second surface of the substrate 102. A solder reflow process may be used to couple the plurality of solder interconnects 114 to the substrate 102.
Stage 11, as shown in FIG. 10D, illustrates a state after the heat pipe 106 is coupled to the back side of the integrated device 103. The heat pipe 106 may be coupled to the back side of the integrated device 103 through a thermal interface material 160. The heat pipe 106 may or may not touch the back side of the integrated device 103. The heat pipe 106 may be the heat pipe 306 of FIG. 3.
Stage 12 illustrates a state after the package 105 is coupled to the substrate 102 through the plurality of solder interconnects 109. The plurality of solder interconnects 109 may be coupled to the plurality of through encapsulation layer interconnects 509. A solder reflow process may be used to couple the package 105 to the plurality of through encapsulation layer interconnects 509. The package 105 may be coupled to the substrate 102 through the plurality of solder interconnects 109, the plurality of through encapsulation layer interconnects 509 and the plurality of through encapsulation layer interconnects 407. The heat pipe 106 may be located between the substrate 102 and the package 105.
Stage 13, as shown in FIG. 10E, illustrate a state after an encapsulation layer 608 is formed and coupled to the package 105. The encapsulation layer 608 may include a mold, a resin and/or an epoxy. The encapsulation layer 608 may be a means for encapsulation. The encapsulation layer 608 may be provided by using a compression and transfer molding process, a sheet molding process, or a liquid molding process. The encapsulation layer 608 may at least partially encapsulate the heat pipe 106 and/or the plurality of solder interconnects 109. The encapsulation layer 108, the encapsulation layer 508 and/or the encapsulation layer 608 may be separate encapsulation layers or they may be considered as one encapsulation layer for the package.

### Exemplary Flow Diagram of a Method for Fabricating a Package Comprising an Embedded Heat Pipe

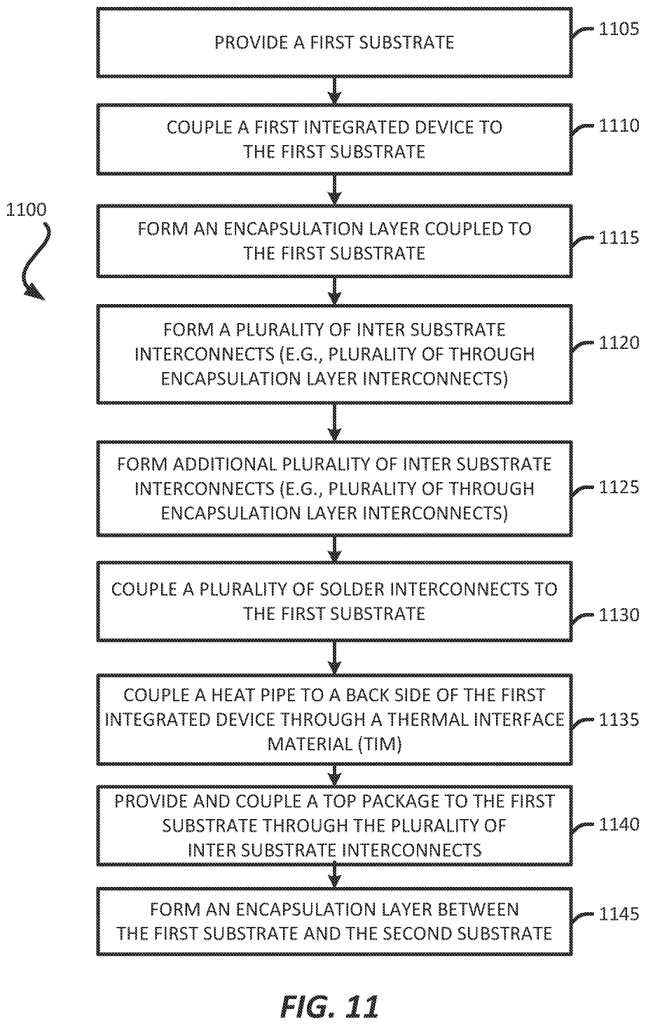

In some implementations, fabricating a package includes several processes. FIG. 11 illustrates an exemplary flow diagram of a method 1100 for providing or fabricating a package. In some implementations, the method 1100 of FIG. 11 may be used to provide or fabricate the package 900 described in the disclosure. However, the method 1100 may be used to provide or fabricate any of the packages (e.g., 100) described in the disclosure.

It should be noted that the method 1100 of FIG. 11 may combine one or more processes in order to simplify and/or clarify the method for providing or fabricating a package. In some implementations, the order of the processes may be changed or modified.

The method provides (at 1105) a first substrate. Stage 1 of FIG. 10A, illustrates and describes an example of a state after a substrate 102 is provided. The substrate 102 may be a first substrate. The substrate 102 includes at least one dielectric layer 120, a plurality of interconnects 122. The substrate 102 may include a first surface (e.g., top surface) and a second surface (e.g., bottom surface). The substrate 102 may include solder resist layers. The substrate 102 may be fabricated using the method as described in FIGS. 13A-13B.

The method couples (at 1110) a first integrated device to the first substrate. Stage 2 of FIG. 10A, illustrates and describes an example of a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102. A front side of the integrated device 103 may be coupled to the substrate 102 through the plurality of pillar interconnects 130 and the plurality of solder interconnects 132.

The method forms (at 1115) an encapsulation layer that is coupled to the first substrate. Stage 3 of FIG. 10A, illustrate and describes an example of a state after an encapsulation layer 108 is formed and coupled to the substrate 102. The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process. The encapsulation layer 108 may at least partially encapsulate the integrated device 103.

In some implementations, forming an encapsulation layer may also include planarizing the encapsulation layer. Stage 4 of FIG. 10A, illustrates and describes an example of a state after planarization of the encapsulation layer 108. A portion of the encapsulation layer 108 may be removed through a grinding process and/or a polishing process. In some implementations, part of the integrated device 103 may also be removed. For example, part of the back side of the integrated device 103 may be removed so that the surface of the back side of the integrated device 103 is planar with the surface of the encapsulation layer 108.

The method forms (at 1120) a plurality of inter substrate interconnects. The plurality of inter substrate interconnects may include a plurality of through encapsulation layer interconnects and/or a plurality of solder interconnects. In some implementations, the plurality of inter substrate interconnects may be formed before the encapsulation layer is formed (at 1115). Stage 5 of FIG. 10B, illustrates and describes an example of a state after a plurality of cavities 1008 are formed in the encapsulation layer 108. The plurality of cavities 1008 may expose portions of the plurality of interconnects 122. A laser ablation process may be used to form the plurality of cavities 1008. However, different implementations may use different processes to form the plurality of cavities 1008.

Stage 6 of FIG. 10B, illustrates and describes an example of a state after a plurality of through encapsulation layer interconnects 407 are formed in the plurality of cavities 1008 of the encapsulation layer 108. A plating process may be used to form the plurality of through encapsulation layer interconnects 407. However, different implementations may use different processes to form the plurality of through encapsulation layer interconnects 407. The plurality of through encapsulation layer interconnects 407 may be an example of a plurality of inter substrate interconnects. In some implementations, the plurality of through encapsulation layer interconnects 407 is formed and then the encapsulation layer 108 is formed that at least partially encapsulates the plurality of through encapsulation layer interconnects 407.

In some implementations, a plurality of solder interconnects (e.g., 107) may be used instead of the plurality of through encapsulation layer interconnects 407. In such instances, the plurality of solder interconnects (e.g., 107) may be coupled to the plurality of interconnects 122 through a solder reflow process, and then the encapsulation layer 108 is formed that at least partially encapsulates the plurality of solder interconnects 107.

The method may form (at 1125) additional plurality of inter substrate interconnects, such as an additional plurality of through encapsulation layer interconnects. Forming the additional plurality of inter substrate interconnects may include forming an additional encapsulation layer. Stage 7 of FIG. 10B, illustrates and describes an example of a state after the encapsulation layer 508 is formed. The encapsulation layer 508 may be formed and coupled to the encapsulation layer 108. The encapsulation layer 508 may include a mold, a resin and/or an epoxy. The encapsulation layer 508 may be a means for encapsulation. The encapsulation layer 508 may be provided by using a compression and transfer molding process, a sheet molding process, or a liquid molding process.

Stage 8 of FIG. 10C, illustrates and describes an example of a state after a plurality of cavities 1018 are formed in the encapsulation layer 508. The plurality of cavities 1018 may expose portions of the plurality of through encapsulation layer interconnects 407. A laser ablation process may be used to form the plurality of cavities 1018. However, different implementations may use different processes to form the plurality of cavities 1018.

Stage 9 of FIG. 10C, illustrates and describes an example of a state after a plurality of through encapsulation layer interconnects 509 are formed in the plurality of cavities 1018 of the encapsulation layer 508. A plating process may be used to form the plurality of through encapsulation layer interconnects 509. However, different implementations may use different processes to form the plurality of through encapsulation layer interconnects 509. The plurality of through encapsulation layer interconnects 509 may be an example of a plurality of inter substrate interconnects. In some implementations, the plurality of through encapsulation layer interconnects 509 is formed and then the encapsulation layer 508 is formed that at least partially encapsulates the plurality of through encapsulation layer interconnects 509.

The method forms and couples (at 1130) a plurality of solder interconnects to the first substrate. Stage 10 of FIG. 10C, illustrates and describes an example of a state after a plurality of solder interconnects 114 are coupled to the second surface of the substrate 102. A solder reflow process may be used to couple the plurality of solder interconnects 114 to the substrate 102

The method couples (at 1135) a heat pipe to the first integrated device through a thermal interface material. Stage 11 of FIG. 10D, illustrates and describes an example of a state after the heat pipe 106 is coupled to the back side of the integrated device 103. The heat pipe 106 may be coupled to the back side of the integrated device 103 through a thermal interface material 160. The heat pipe 106 may or may not touch the back side of the integrated device 103. The heat pipe 106 may be the heat pipe 306 of FIG. 3.

The method couples (at 1140) a package (e.g., top package) to the first substrate through a plurality of inter substrate interconnects. Stage 12 of FIG. 10D, illustrates and describes an example of a state after the package 105 is coupled to the substrate 102 through the plurality of solder interconnects 109. The plurality of solder interconnects 109 may be coupled to the plurality of through encapsulation layer interconnects 509. A solder reflow process may be used to couple the package 105 to the plurality of through encapsulation layer interconnects 509. The package 105 may be coupled to the substrate 102 through the plurality of solder interconnects 109, the plurality of through encapsulation layer interconnects 509 and the plurality of through encapsulation layer interconnects 407. The heat pipe 106 may be located between the substrate 102 and the package 105.

The method forms (at 1145) an encapsulation layer between the first substrate and the second substrate. The encapsulation layer may at least partially encapsulate the heat pipe. Stage 13 of FIG. 10E, illustrate and describes an example of a state after an encapsulation layer 608 is formed and coupled to the package 105. The encapsulation layer 608 may include a mold, a resin and/or an epoxy. The encapsulation layer 608 may be a means for encapsulation. The encapsulation layer 608 may be provided by using a compression and transfer molding process, a sheet molding process, or a liquid molding process. The encapsulation layer 608 may at least partially encapsulate the heat pipe 106 and/or the plurality of solder interconnects 109. The encapsulation layer 108, the encapsulation layer 508 and/or the encapsulation layer 608 may be separate encapsulation layers or they may be considered as one encapsulation layer for the package.

### Exemplary Sequence for Fabricating a Device Comprising a Package With an Embedded Heat Pipe

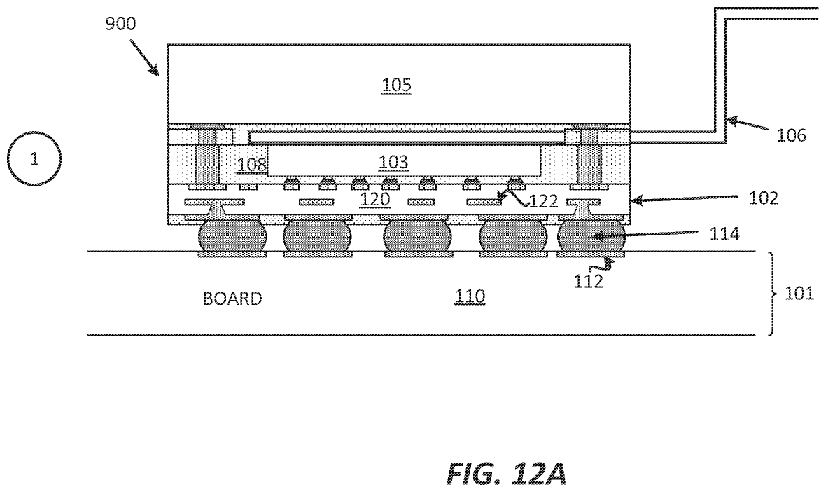

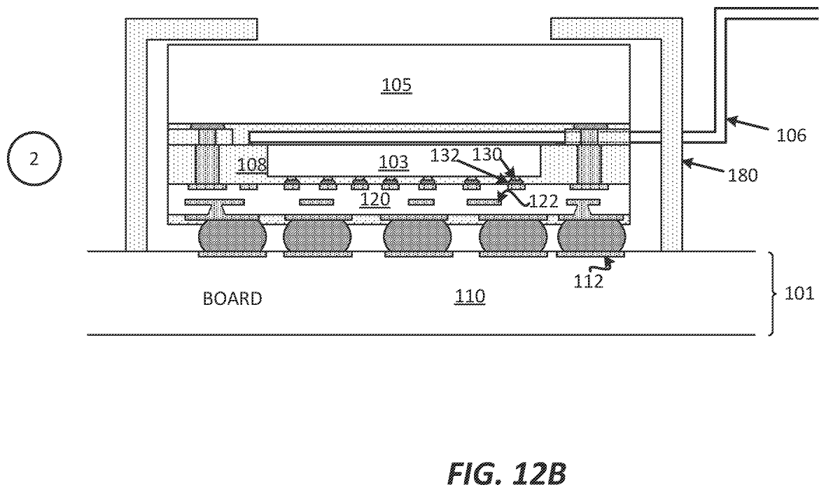

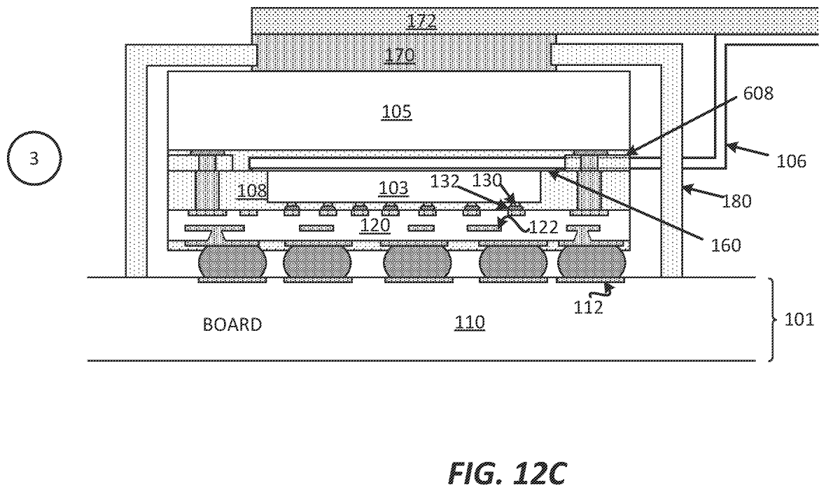

In some implementations, fabricating a device with a package includes several processes. FIGS. 12A-12E illustrate an exemplary sequence for providing or fabricating a device with a package. In some implementations, the sequence of FIGS. 12A-12C may be used to provide or fabricate a device the package 900. However, the process of FIGS. 12A-12C may be used to fabricate any of devices with the packages (e.g., 100) described in the disclosure.

It should be noted that the sequence of FIGS. 12A-12C may combine one or more stages in order to simplify and/or clarify the sequence for providing or fabricating device with a package. In some implementations, the order of the processes may be changed or modified. In some implementations, one or more of processes may be replaced or substituted without departing from the scope of the disclosure.

Stage 1, as shown in FIG. 12A, illustrates a state after the package 900 is coupled to the board 101 through a plurality of solder interconnects 114. A solder reflow process may be used to couple the package 900 to the board 101. The package 900 may include a heat pipe 106 that is at least partially embedded in the package 900.

Stage 2, as shown in FIG. 12B, illustrates a state after a frame 180 is coupled to the board 101. The frame 180 may laterally surround at least part of the package 900. A solder reflow process may be used to couple the frame 180 through a plurality of solder interconnects. In some implementations, an adhesive may be used to couple the frame 180 to the board 101. The frame 180 may include several openings. The heat pipe 106 may extend through one of the openings of the frame 180.

Stage 3, as shown in FIG. 12C, illustrates a state after a heat sink 172 is coupled to a back side of the package 105 through a thermal interface material 170. At least part of the thermal interface material 170 may located in an opening of the frame 180. The opening of the frame 180 may vertically overlap with the package 105. The heat sink 172 may also be coupled to the heat pipe 106. A thermal interface material may be used to couple the heat pipe 106 to the heat sink 172.

### Exemplary Sequence for Fabricating a Substrate

In some implementations, fabricating a substrate includes several processes. FIGS. 13A-13B illustrate an exemplary sequence for providing or fabricating a substrate. In some implementations, the sequence of FIGS. 13A-13B may be used to provide or fabricate the substrate 102. However, the process of FIGS. 13A-13B may be used to fabricate any of the substrates described in the disclosure.

It should be noted that the sequence of FIGS. 13A-13B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.
Stage 1, as shown in FIG. 13A, illustrates a state after a carrier 1300 is provided. A seed layer 1301 may be located over the carrier 1300.
Stage 2 illustrates a state after a plurality of interconnects 1312 are formed. The interconnects 1312 may be located over the seed layer 1301. A lithography process, a plating process, a strip process and/or an etching process may be used to form the plurality of interconnects 1312.
Stage 3 illustrates a state after a dielectric layer 1310 is formed over the carrier 1300, the seed layer 1301 and the plurality of interconnects 1312. A deposition and/or lamination process may be used to form the dielectric layer 1310. The dielectric layer 1310 may include prepreg and/or polyimide. The dielectric layer 1310 may include a photo-imageable dielectric. However, different implementations may use different materials for the dielectric layer.
Stage 4 illustrates a state after a plurality of cavities 1313 is formed in the dielectric layer 1310. The plurality of cavities 1313 may be formed using an etching process (e.g., photo etching process), a laser process, an exposure process and/or a development process.
Stage 5 illustrates a state after interconnects 1322 are formed in and over the dielectric layer 1310, including in and over the plurality of cavities 1313. For example, a via, pad and/or traces may be formed. A lithography process, a plating process, a strip process and/or an etching process may be used to form the interconnects.
Stage 6, as shown in FIG. 13B, illustrates a state after a dielectric layer 1320 is formed over the dielectric layer 1310 and the plurality of interconnects 1322. A deposition and/or lamination process may be used to form the dielectric layer 1320. The dielectric layer 1320 may include prepreg and/or polyimide. The dielectric layer 1320 may include a photo-imageable dielectric. However, different implementations may use different materials for the dielectric layer.
Stage 7, illustrates a state after a plurality of cavities 1323 is formed in the dielectric layer 120. The dielectric layer 120 may represent the dielectric layer 1310 and/or the dielectric layer 1320. The plurality of cavities 1323 may be formed using an etching process (e.g., photo etching process), a laser process, an exposure process and/or a development process.
Stage 8 illustrates a state after interconnects 1332 are formed in and over the dielectric layer 120, including in and over the plurality of cavities 1323. For example, a via, pad and/or traces may be formed. A lithography process, a plating process, a strip process and/or an etching process may be used to form the interconnects.
Stage 9 illustrates a state after the carrier 1300 is decoupled (e.g., detached, removed, grinded out) from at least one dielectric layer 120 and the seed layer 1301, portions of the seed layer 1301 are removed (e.g., etched out), leaving the substrate 102 that includes at least one dielectric layer 120 and the plurality of interconnects 122. The plurality of interconnects 122 may represent the plurality of interconnects 1312, the plurality of interconnects 1322 and/or the plurality of interconnects 1332.
Stage 10 illustrates a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126. The solder resist layer 124 and/or the solder resist layer 126 may include openings. An etching process, an exposure process and/or a development process may be used to form the openings in the solder resist layer 124 and/or the openings in the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

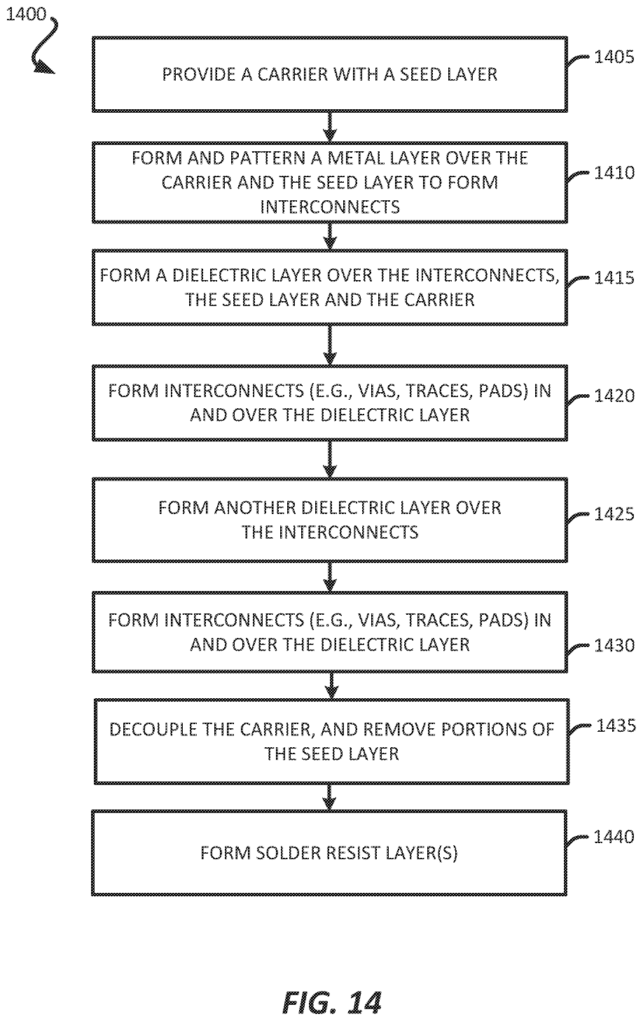

In some implementations, fabricating a substrate includes several processes. FIG. 14 illustrates an exemplary flow diagram of a method 1400 for providing or fabricating a substrate. In some implementations, the method 1400 of FIG. 14 may be used to provide or fabricate the substrate(s) of the disclosure. For example, the method 1400 of FIG. 14 may be used to fabricate the substrate 102.

It should be noted that the method 1400 of FIG. 14 may combine one or more processes in order to simplify and/or clarify the method for providing or fabricating a substrate. In some implementations, the order of the processes may be changed or modified.

The method provides (at 1405) a carrier with a seed layer. Stage 1 of FIG. 13A, illustrates and describes an example of a state after a carrier 1300 is provided. A seed layer 1301 may be located over the carrier 1300.

The method forms and patterns (at 1410) a plurality of interconnects. Stage 2 of FIG. 13A, illustrates and describes an example of a state after a plurality of interconnects 1312 are formed. The interconnects 1312 may be located over the seed layer 1301. A lithography process, a plating process, a strip process and/or an etching process may be used to form the plurality of interconnects 1312. The interconnects 1312 may represent at least some of the interconnects from the plurality of interconnects 122.

The method forms (at 1420) a dielectric layer. Stage 3 of FIG. 13A, illustrates and describes an example of a state after a dielectric layer 1310 is formed over the carrier 1300, the seed layer 1301 and the plurality of interconnects 1312. A deposition and/or lamination process may be used to form the dielectric layer 1310. The dielectric layer 1310 may include prepreg and/or polyimide. The dielectric layer 1310 may include a photo-imageable dielectric. However, different implementations may use different materials for the dielectric layer.

The method forms (at 1420) a plurality of interconnects. Forming a plurality of interconnects may including forming a plurality of cavities in a dielectric layer and a performing a plating process. Stage 4 of FIG. 13A, illustrates and describes an example of a state after a plurality of cavities 1313 is formed in the dielectric layer 1310. The plurality of cavities 1313 may be formed using an etching process (e.g., photo etching process), a laser process, an exposure process and/or a development process.

Stage 5 of FIG. 13A, illustrates and describes an example of a state after interconnects 1322 are formed in and over the dielectric layer 1310, including in and over the plurality of cavities 1313. For example, a via, pad and/or traces may be formed. A lithography process, a plating process, a strip process and/or an etching process may be used to form the interconnects.

The method forms (at 1425) another dielectric layer. Stage 6 of FIG. 13B, illustrates and describes an example of a state after a dielectric layer 1320 is formed over the dielectric layer 1310 and the plurality of interconnects 1322. A deposition and/or lamination process may be used to form the dielectric layer 1320. The dielectric layer 1320 may include prepreg and/or polyimide. The dielectric layer 1320 may include a photo-imageable dielectric. However, different implementations may use different materials for the dielectric layer.

The method forms (at 1430) a plurality of interconnects. Forming a plurality of interconnects may including forming a plurality of cavities in a dielectric layer and a performing a plating process. Stage 7 of FIG. 13B, illustrates and describes an example of a state after a plurality of cavities 1323 is formed in the dielectric layer 120. The dielectric layer 120 may represent the dielectric layer 1310 and/or the dielectric layer 1320. The plurality of cavities 1323 may be formed using an etching process (e.g., photo etching process), a laser process, an exposure process and/or a development process.

Stage 8 of FIG. 13B, illustrates and describes an example of a state after interconnects 1332 are formed in and over the dielectric layer 120, including in and over the plurality of cavities 1323. For example, a via, pad and/or traces may be formed. A lithography process, a plating process, a strip process and/or an etching process may be used to form the interconnects.

The method decouples (at 1435) a carrier. Stage 9 of FIG. 13B, illustrates and describes an example of a state after the carrier 1300 is decoupled (e.g., detached, removed, grinded out) from at least one dielectric layer 120 and the seed layer 1301, portions of the seed layer 1301 are removed (e.g., etched out), leaving the substrate 102 that includes at least one dielectric layer 120 and the plurality of interconnects 122. The plurality of interconnects 122 may represent the plurality of interconnects 1312, the plurality of interconnects 1322 and/or the plurality of interconnects 1332.

The method forms (at 1440) solder resist layers. Stage 10 of FIG. 13B, illustrates and describes an example of a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126. An etching process, an exposure process and/or a development process may be used to form the openings in the solder resist layer 124 and/or the openings in the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Packages

The disclosure describes a package on package that may include a top package (e.g., package 105). The top package may have different shapes, sizes, and/or configurations. FIGS. 15-16 illustrate examples of a top package that may be implemented in a package on package. FIG. 15 illustrates a package 1500 that may be an example of the package 105. The package 1500 includes a substrate 1504, an integrated device 1503, an integrated device 1505, and an encapsulation layer 1508. The substrate 1504 includes at least one dielectric layer 1540 and a plurality of interconnects 1542. The integrated device 1503 is coupled to the substrate 1504 through a plurality of pillar interconnects 1530 and a plurality of solder interconnects 1532. The integrated device 1505 is coupled to the substrate 1504 through a plurality of pillar interconnects 1550 and a plurality of solder interconnects 1552. The encapsulation layer 1508 is coupled to the substrate 1504. The encapsulation layer 1508 may at least partially encapsulate the integrated device 1503 and the integrated device 1505. The plurality of solder interconnects 109 are coupled to the plurality of interconnects 1542.

FIG. 16 illustrates a package 1600 that may be an example of the package 105. The package 1600 includes a substrate 1604, an integrated device 1611, an integrated device 1612, an integrated device 1613, an integrated device 1621, an integrated device 1622, an integrated device 1623, a plurality of wire bonds 1610, a plurality of wire bonds 1620 and an encapsulation layer 1608. The substrate 1604 includes at least one dielectric layer 1640 and a plurality of interconnects 1642. The plurality of solder interconnects 109 are coupled to the plurality of interconnects 1642.

The integrated device 1611 is coupled to the substrate 1604. The integrated device 1612 is coupled to integrated device 1611. The integrated device 1613 is coupled to integrated device 1612. The integrated device 1611, the integrated device 1612 and the integrated device 1613 may be a stack of integrated devices. The plurality of wire bonds 1610 are coupled to the substrate 1604 and the stack of integrated devices comprising the integrated device 1611, the integrated device 1612 and the integrated device 1613. The wire bond 1610a is coupled to the integrated device 1611 and a first interconnect from the plurality of interconnects 1642 of the substrate 1604. The wire bond 1610b is coupled to the integrated device 1612 and a second interconnect from the plurality of interconnects 1642 of the substrate 1604. The wire bond 1610c is coupled to the integrated device 1613 and a third interconnect from the plurality of interconnects 1642 of the substrate 1604.

The integrated device 1621 is coupled to the substrate 1604. The integrated device 1622 is coupled to integrated device 1621. The integrated device 1623 is coupled to integrated device 1622. The integrated device 1621, the integrated device 1622 and the integrated device 1623 may be a stack of integrated devices. The plurality of wire bonds 1620 are coupled to the substrate 1604 and the stack of integrated devices comprising the integrated device 1621, the integrated device 1622 and the integrated device 1623. The wire bond 1620a is coupled to the integrated device 1621 and a first interconnect from the plurality of interconnects 1642 of the substrate 1604. The wire bond 1620b is coupled to the integrated device 1622 and a second interconnect from the plurality of interconnects 1642 of the substrate 1604. The wire bond 1620c is coupled to the integrated device 1623 and a third interconnect from the plurality of interconnects 1642 of the substrate 1604.

The encapsulation layer 1608 may be coupled to the substrate 1604. The encapsulation layer 1608 may at least partially encapsulate the integrated device 1611, the integrated device 1612, the integrated device 1613, the integrated device 1621, the integrated device 1622, the integrated device 1623, the plurality of wire bonds 1610, and/or the plurality of wire bonds 1620.

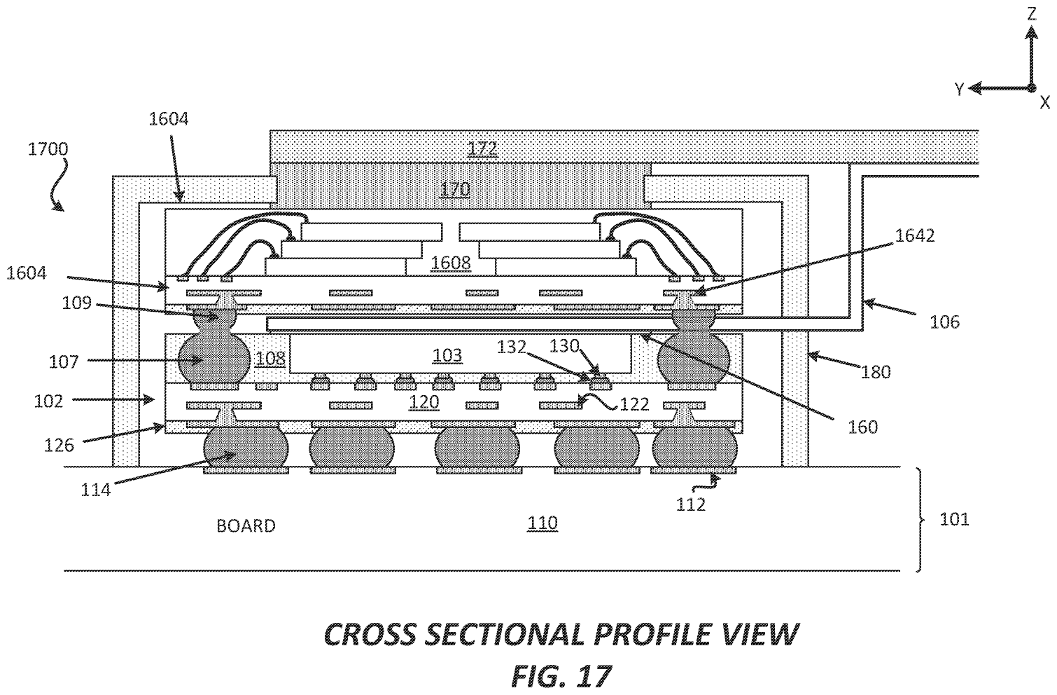

FIG. 17 illustrates a cross sectional profile view of a package 1700 that includes an embedded heat pipe. The embedded heat pipe is located between two substrates. The package 1700 may be implemented as part of a package on package (POP). The package 1700 is coupled to a board 101 through a plurality of solder interconnects 114. The board 101 includes at least one board dielectric layer 110 and a plurality of board interconnects 112. The board 101 may include a printed circuit board (PCB).

The package 1700 is similar to the package 100. The package 1700 illustrates the package 100 of FIG. 1, with the package 105 being replaced with the package 1600 of FIG. 16. The package 1700 includes a substrate 102 (e.g., first substrate), an integrated device 103 (e.g., first integrated device), a substrate 1604 (e.g., second substrate, interposer), an integrated device 1611, an integrated device 1612, an integrated device 1613, an integrated device 1621, an integrated device 1622, an integrated device 1623, a plurality of wire bonds 1610, a plurality of wire bonds 1620, an encapsulation layer 1608, a heat pipe 106, and an encapsulation layer 108. The substrate 102 includes a dielectric layer 120, a plurality of interconnects 122 and a solder resist layer 126. The substrate 102 is coupled to the board 101 through the plurality of solder interconnects 114. The integrated device 103 is coupled to the substrate 102 through at least a plurality of solder interconnects 132. For example, the integrated device 103 is coupled to a plurality of interconnects 122 of the substrate 102 through a plurality of pillar interconnects 130 and/or a plurality of solder interconnects 132. A plurality of solder interconnects 107 are coupled to the plurality of interconnects 122 of the substrate 102. The encapsulation layer 108 may at least partially encapsulate the integrated device 103 and the plurality of solder interconnects 107.

The substrate 1604 is coupled to the substrate 102 through a plurality of solder interconnects 109 and a plurality of solder interconnects 107. The plurality of solder interconnects 109 may be coupled to the plurality of solder interconnects 107. In some implementations, the plurality of solder interconnects 109 and the plurality of solder interconnects 107 may be considered part of the same plurality of solder interconnects. The plurality of solder interconnects 109 and the plurality of solder interconnects 107 may be considered examples of inter substrate interconnects. The plurality of solder interconnects 109 may be coupled to the plurality of interconnects 1642 of the substrate 1604. The integrated device 103, the encapsulation layer 108, the plurality of solder interconnects 107 and the plurality of solder interconnects 109 are located between the substrate 102 and the substrate 1604. The encapsulation layer 108 may include a mold, a resin and/or an epoxy. The heat sink 172 may be coupled to the encapsulation layer 1608 through the thermal interface material 170.

The package 1600 and/or the package 1500 may replace the package 105 in any of the other packages in a similar matter.

### Exemplary Electronic Devices

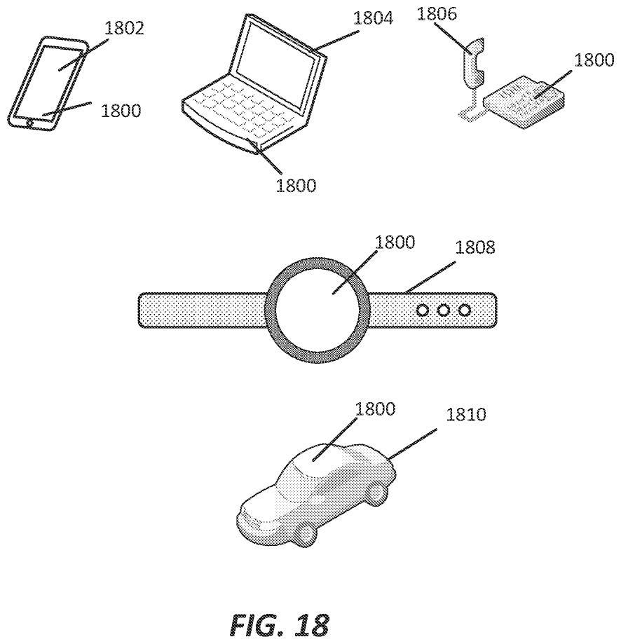

FIG. 18 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1802, a laptop computer device 1804, a fixed location terminal device 1806, a wearable device 1808, or automotive vehicle 1810 may include a device 1800 as described herein. The device 1800 may be, for example, any of the devices and/or integrated circuit (IC) packages described herein. The devices 1802, 1804, 1806 and 1808 and the vehicle 1810 illustrated in FIG. 18 are merely exemplary. Other electronic devices may also feature the device 1800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-9, 10A-10E, 11, 12A-12C, 13A-13B and 14-18 may be rearranged and/or combined into a single component, process, feature or function or embodied in several components, processes, or functions. Additional elements, components, processes, and/or functions may also be added without departing from the disclosure. It should also be noted FIGS. 1-9, 10A-10E, 11, 12A-12C, 13A-13B and 14-18 and its corresponding description in the present disclosure is not limited to dies and/or ICs. In some implementations, FIGS. 1-9, 10A-10E, 11, 12A-12C, 13A-13B and 14-18 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: A device comprising a board; a first package coupled to the board through a plurality of solder interconnects, wherein the first package comprises: a first substrate; a first integrated device coupled to the first substrate; a heat pipe coupled to the first integrated device through a thermal interface material; a second package coupled to the first substrate through a through a plurality of inter substrate interconnects; and an encapsulation layer located between the first substrate and the second package.
Aspect 2: The device of aspect 1, wherein the heat pipe is coupled to a back side of the first integrated device through the thermal interface material.
Aspect 3: The device of aspects 1 through 2, wherein the second package comprises a second substrate and a second integrated device coupled to the second substrate; and wherein the device further comprises a heat sink coupled to the second package through a second thermal interface material.
Aspect 4: The device of aspect 3, wherein the heat sink is further coupled to the heat pipe.
Aspect 5: The device of aspects 1 through 2, wherein the second package comprises a second substrate and a second integrated device coupled to the second substrate; and a vapor chamber coupled to the second package through a second thermal interface material.
Aspect 6: The device of aspect 5, wherein the heat sink is further coupled to the heat pipe.
Aspect 7: The device of aspects 1 through 6, wherein the plurality of inter substrate interconnects comprise a plurality of solder interconnects.
Aspect 8: The device of aspects 1 through 7, wherein the plurality of inter substrate interconnects comprise a plurality of through encapsulation layer interconnects.
Aspect 9: The device of aspects 1 through 8, wherein the encapsulation layer at least partially encapsulates the plurality of inter substrate interconnects.
Aspect 10: The device of aspects 1 through 9, wherein the heat pipe is a two phase heat dissipation device.
Aspect 11: The device of aspects 1 through 10, wherein the heat pipe is embedded in the encapsulation layer.
Aspect 12: The device of aspects 1 through 11, wherein the encapsulation layer at least partially encapsulates the first integrated device, the plurality of inter substrate interconnects and the heat pipe.
Aspect 13: The device of aspects 1 through 12, wherein the heat pipe is located laterally between two inter substrate interconnects from the plurality of inter substrate interconnects.
Aspect 14: The device of aspects 1 through 13, wherein the heat pipe extends in a horizontal direction and a vertical direction.
Aspect 15: The device of aspect 14, wherein the heat pipe that extends in a horizontal direction extends in a first horizontal direction and a second horizontal direction.
Aspect 16: The device of aspects 14 through 15, further comprising a frame coupled to the board.
Aspect 17: The device of aspect 16, wherein the heat pipe extends through the frame.
Aspect 18: A package on package comprising a first package comprising: a first substrate; a first integrated device coupled to the first substrate; a heat pipe coupled to the first integrated device through a thermal interface material; a second package coupled to the first package through a through a plurality of inter substrate interconnects; and an encapsulation layer located between the first substrate and the second package.
Aspect 19: The package on package of aspect 18, wherein the heat pipe is coupled to a back side of the first integrated device through the thermal interface material.
Aspect 20: The package of package of aspect 18, wherein the second package comprises a second substrate; and a second integrated device coupled to the second substrate; and wherein the package on package further comprises a heat sink coupled to the second package through a second thermal interface material.
Aspect 21: The package on package of aspects 18 through 20, wherein the package on package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
Aspect 22: The device of aspects 1 through 17, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a board;
a first package coupled to the board through a plurality of solder interconnects, wherein the first package comprises:
a first substrate;
a first integrated device coupled to the first substrate;
a heat pipe coupled to the first integrated device through a thermal interface material;
a second package coupled to the first substrate through a through a plurality of inter substrate interconnects; and
an encapsulation layer located between the first substrate and the second package.

2. The device of claim 1, wherein the heat pipe is coupled to a back side of the first integrated device through the thermal interface material.

3. The device of claim 1,
wherein the second package comprises a second substrate and a second integrated device coupled to the second substrate; and
wherein the device further comprises a heat sink coupled to the second package through a second thermal interface material.

4. The device of claim 3, wherein the heat sink is further coupled to the heat pipe.

5. The device of claim 1,
wherein the second package comprises a second substrate and a second integrated device coupled to the second substrate; and
a vapor chamber coupled to the second package through a second thermal interface material.

6. The device of claim 5, wherein the heat sink is further coupled to the heat pipe.

7. The device of claim 1, wherein the plurality of inter substrate interconnects comprise a plurality of solder interconnects.

8. The device of claim 1, wherein the plurality of inter substrate interconnects comprise a plurality of through encapsulation layer interconnects.

9. The device of claim 1, wherein the encapsulation layer at least partially encapsulates the plurality of inter substrate interconnects.

10. The device of claim 1, wherein the heat pipe is a two phase heat dissipation device.

11. The device of claim 1, wherein the heat pipe is embedded in the encapsulation layer.

12. The device of claim 1, wherein the encapsulation layer at least partially encapsulates the first integrated device, the plurality of inter substrate interconnects and the heat pipe.

13. The device of claim 1, wherein the heat pipe is located laterally between two inter substrate interconnects from the plurality of inter substrate interconnects.

14. The device of claim 1, wherein the heat pipe extends in a horizontal direction and a vertical direction.

15. The device of claim 14, wherein the heat pipe that extends in a horizontal direction extends in a first horizontal direction and a second horizontal direction.

16. The device of claim 14, further comprising a frame coupled to the board.

17. The device of claim 16, wherein the heat pipe extends through the frame.

18. A package on package comprising:
a first package comprising:
a first substrate;
a first integrated device coupled to the first substrate; and
a heat pipe coupled to the first integrated device through a thermal interface material;
a second package coupled to the first package through a through a plurality of inter substrate interconnects; and
an encapsulation layer located between the first substrate and the second package.

19. The package on package of claim 18, wherein the heat pipe is coupled to a back side of the first integrated device through the thermal interface material.

20. The package on package of claim 18, wherein the second package comprises:
a second substrate; and
a second integrated device coupled to the second substrate, and
wherein the package on package further comprises a heat sink coupled to the second package through a second thermal interface material.
